(19) United States
(12) Patent Application Publication
(10) Pub. No.: US 2025/0227944 A1
(43) Pub. Date: Jul. 10, 2025

(54) DIODE AND TRANSISTOR DEVICES AND FABRICATION TECHNIQUES

(71) Applicant: Murata Manufactunng Co., Ltd., Kyoto (JP)

(72) Inventors: Jagar Singh, Clifton Park, NY (US); David E. Bockelman, Dripping Springs, TX (US)

(21) Appl. No.: 18/408,508

(22) Filed: Jan. 9, 2024

(51) Int. Cl. H01L 29/66; H01L 21/265; H01L 21/266; H01L 21/308; H01L 21/311; H01L 29/40; H01L 29/735

(52) U.S. Cl. CPC H10D 10/061; H01L 21/2652; H01L 21/266; H01L 21/308; H01L 21/31144; H10D 10/60; H10D 64/01

(57) ABSTRACT

In accordance with various embodiments, a method for fabricating a device is provided. The method includes providing a semiconductor layer-stack having one or more layers and a high resistivity substrate layer; implanting a first dopant to form a first region; etching one or more vias through the one or more layers and into a top portion of the high resistivity substrate layer; implanting a second dopant to form one or more second regions; and implanting the first dopant to form one or more third regions. The method also includes depositing a metal in the vias to form one or more metal contacts, thereby forming a diode or a bipolar junction transistor. Either the second or third regions can include a floating region to improve the transistor performance. The transistor can be a PNP or a NPN bipolar junction transistor, depending on the dopants.

### FIELD OF INVENTION

Embodiments of the present disclosure relate generally to diode and transistor devices and, more particularly, to fabrication techniques of diode and transistor devices using a silicon-on-insulator.

### BACKGROUND

Fabricating a diode or a bipolar junction transistor using traditional semiconductor processes is typical. However, as the processing technology advances, the demand for higher performing devices also increases, and thus necessitating further improvements in device fabrication techniques. There is a need for improved device fabrication methods beyond the state of the art that can be used to manufacture a diode or a transistor with superior performance.

### SUMMARY

In accordance with various embodiments, the disclosure relates to diodes and transistors, and various fabricating techniques used to produce such devices.

In accordance with one or more embodiments, a method for fabricating a device is provided. The method includes providing a semiconductor layer-stack having one or more layers and a high resistivity substrate layer; implanting a first dopant using a first mask to form a first region spanning a first lateral portion of the high resistivity substrate layer; etching a via through the one or more layers and into a top portion of the high resistivity substrate layer; implanting a second dopant using a second mask to form one or more second regions spanning one or more second lateral portions of the high resistivity substrate layer, wherein the one or more second lateral portions resides within the first lateral portion; and implanting the first dopant using a third mask to form one or more third regions spanning one or more third lateral portions of the high resistivity substrate layer, wherein the one or more third lateral portions resides within the first lateral portion.

In accordance with various embodiments, a method for fabricating a bipolar junction transistor is provided. The method includes providing a semiconductor layer-stack comprising a top silicon layer, a buried oxide layer, and a high resistivity substrate layer; implanting a first dopant using a first mask to form a negative region spanning a first lateral portion of the high resistivity substrate layer; etching one or more vias through the top silicon layer, the buried oxide layer, and a top portion of the high resistivity substrate layer; implanting a second dopant using a second mask to form one or more positive regions spanning one or more second lateral portions of the high resistivity substrate layer, wherein the one or more second lateral portions resides within the first lateral portion; implanting the first dopant using a third mask to form one or more third regions spanning one or more third lateral portions of the high resistivity substrate layer, wherein the one or more third lateral portions resides within the first lateral portion; and depositing a metal in the one or more etched vias to form one or more metal contacts, wherein the one or more metal contacts are formed at centers of the one or more positive regions, thereby forming a bipolar junction transistor.

In accordance with various embodiments, a device produced using one or more fabricated techniques is described herein. The device includes a semiconductor layer-stack having one or more layers and a high resistivity substrate layer, wherein the high resistivity substrate layer comprises: a first region spanning a first lateral portion of the high resistivity substrate layer, wherein the first region comprises a first dopant, one or more second regions spanning one or more second lateral portions of the high resistivity substrate layer, wherein the one or more second lateral portions resides within the first lateral portion, wherein the one or more second regions comprise a second dopant, and one or more third regions spanning one or more third lateral portions of the high resistivity substrate layer, wherein the one or more third lateral portions resides within the first lateral portion, wherein the one or more third regions comprise the first dopant, a plurality of vias formed through the one or more layers and within a top portion of the high resistivity substrate layer, and a plurality of metal contacts, wherein each of the plurality of metal contacts is formed within a via of the plurality of vias.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification.

### BRIEF DESCRIPTION OF THE DRAWINGS

For a more complete understanding of the principles disclosed herein, and the advantages thereof, reference is now made to the following descriptions taken in conjunction with the accompanying drawings, in which:

FIGS. 1A and 1B illustrate a bipolar junction transistor device, in accordance with various embodiments.

FIG. 2 illustrates an example application in which the bipolar junction transistor device can be used, in accordance with one or more embodiments.

FIGS. 3A-3D show various plots illustrating silicon-on-insulator (SOI) based diode and bipolar transistor performances.

FIGS. 4A-4D show various a schematic diagram and various plots illustrating an example diode and bipolar transistor performances.

FIG. 5 illustrates a method of fabricating a device, in accordance with various embodiments.

FIG. 6 illustrates a method of fabricating a bipolar junction transistor, in accordance with various embodiments.

It is to be understood that the figures are not necessarily drawn to scale, nor are the objects in the figures necessarily drawn to scale in relationship to one another. The figures are depictions that are intended to bring clarity and understanding to various embodiments of apparatuses, systems, and methods disclosed herein. Wherever possible, the same reference numbers will be used throughout the drawings to refer to the same or like parts. Moreover, it should be appreciated that the drawings are not intended to limit the scope of the present teachings in any way.

### DETAILED DESCRIPTION

Current disclosure describes one or more embodiments of the diode and transistor devices and fabricating methods for producing such devices. The embodiments disclosed herein can be used to fabricate diodes and bipolar junction transistor devices, in particular. The disclosed fabricating method may include using a semiconductor layer-stack, such as a silicon-on-insulator (SOI) substrate comprising a top silicon layer, a buried oxide layer, and a high resistivity substrate layer. To produce a PNP bipolar junction transistor, first, a dopant, such as boron may be implanted using a mask to form a negative region (designated as “deep Nwell” region) on the SOI substrate. This first region can include a lateral portion on the high resistivity substrate layer of the SOI substrate. Then, the SOI substrate can be etched to form one or more vias through the top silicon layer, the buried oxide layer, and a top portion of the high resistivity substrate layer. Once the vias are formed, a second dopant species, such as phosphorous or arsenic, can be implanted using a different mask to form one or more positive regions. These positive regions (designated as “P+ regions) can span one or more lateral portions in the high resistivity substrate layer, that is within the first lateral portion/deep Nwell region. Once P+ regions are formed, the SOI substrate can be further implanted with the first dopant, such as boron, using a third mask to form one or more negative regions (designated as “N+ regions”) spanning one or more third lateral portions of the high resistivity substrate layer. These N+ regions also reside within the deep Nwell region. Once these P+ regions and N+ regions, which respectively serve as Emitter/Collector (P+ regions) and Base (N+ regions) are formed, a metal can be deposited into the etched vias to form metal contacts to form a positive-negative-positive (PNP) bipolar junction transistor device. Using the same disclosed fabrication techniques, negative-positive-negative (NPN) bipolar junction transistor devices can also be produced by swapping the dopant species, e.g., using phosphorous or arsenic as the first dopant species and using boron as the second dopant species, to form deep Pwell region, and respective P+ regions and N+ regions.

A bipolar junction transistor device produced using one or more fabricated techniques is described herein. The bipolar junction transistor device may have a semiconductor layer-stack, such as a SOI substrate with one or more layers and a high resistivity substrate layer. Within the SOI substrate of the bipolar junction transistor device, the high resistivity substrate layer can include a doped region (designated as “deep Nwell” region” that spans a lateral portion in the high resistivity substrate layer that has been doped with a dopant, such as, boron. The SOI substrate may also include regions that have been doped with a second dopant species, such as phosphorous or arsenic, spanning one or more second lateral portions of the high resistivity substrate layer. These regions (designated as “P+ regions”) can include one or more second lateral portions resides within the deep Nwell region. The SOI substrate of the bipolar junction transistor device can also include additional regions that have been doped with the first dopant, such as boron, that span one or more additional portions of the high resistivity substrate layer. These regions (designated as “N+ regions”) can also reside within the deep Nwell region. At centers of the P+ regions and N+ regions are vias that have been formed through the one or more layers and within a top portion of the high resistivity substrate layer. The bipolar junction transistor device may also have a plurality of metal contacts that are formed inside the vias for used as metal contacts for the bipolar junction transistor. The resulting bipolar junction transistor device is a PNP bipolar junction transistor device. Using similar disclosed fabrication techniques, a NPN bipolar junction transistor device can also be produced, for example, by swapping the dopant species, e.g., using phosphorous or arsenic as the first dopant species and using boron as the second dopant species, to form deep Pwell region, and respective P+ regions and N+ regions.

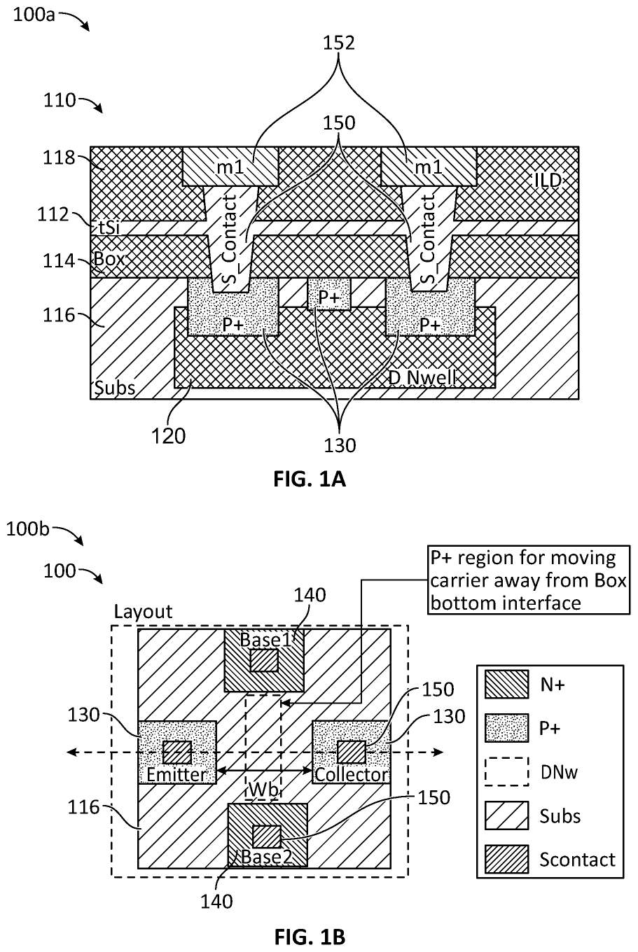

The disclosed fabrication techniques are further described with respect to FIGS. 1-6, in accordance with various embodiments.

FIGS. 1A and 1B illustrate a bipolar junction transistor device 100, in accordance with various embodiments. FIG. 1A illustrates a cross-sectional view 100a of the bipolar junction transistor device 100 and FIG. 1B illustrates a top view 100b of the bipolar junction transistor device 100. As illustrated in FIGS. 1A and 1B, the bipolar junction transistor device 100 includes a semiconductor layer-stack 100, which also referred to herein as “SOI substrate 100”, with one or more layers, including a top or thin silicon layer 112, a buried oxide layer 114, and a high resistivity substrate layer 116. As illustrated, the semiconductor layer-stack 110 may also include an intermediate or interlayer dielectric layer (ILD) 118 disposed on top of the semiconductor layer-stack 110.

Within the SOI substrate of the bipolar junction transistor device 100, the high resistivity substrate layer 116 can include a doped region 120 (designated as “deep Nwell” region 120″ that spans a lateral portion in the high resistivity substrate layer 116 that has been doped with a dopant, such as, boron. The SOI substrate 110 may also include regions 130 that have been doped with a second dopant species, such as phosphorous or arsenic, spanning one or more second lateral portions of the high resistivity substrate layer. These regions (designated as “P+ regions”) can include one or more second lateral portions resides within the deep Nwell region 120. The SOI substrate 110 of the bipolar junction transistor device 100 can also include additional regions 140 that have been doped with the first dopant, such as boron, that span one or more additional portions of the high resistivity substrate layer. These regions 140 (designated as “N+ regions 140”) can also reside within the deep Nwell region 120. At centers of the P+ regions and N+ regions are vias 150 that have been formed through the one or more layers and within a top portion of the high resistivity substrate layer. The bipolar junction transistor device may also have a plurality of metal contacts 152 that are formed inside the vias for used as metal contacts 152 for the bipolar junction transistor. The bipolar junction transistor device 100 illustrated in FIGS. 1A and 1B is a PNP bipolar junction transistor device. Using similar disclosed fabrication techniques described herein, a NPN bipolar junction transistor device can also be produced, for example, by swapping the dopant species, e.g., using phosphorous or arsenic as the first dopant species and using boron as the second dopant species, to form deep Pwell region, and respective P+ regions and N+ regions.

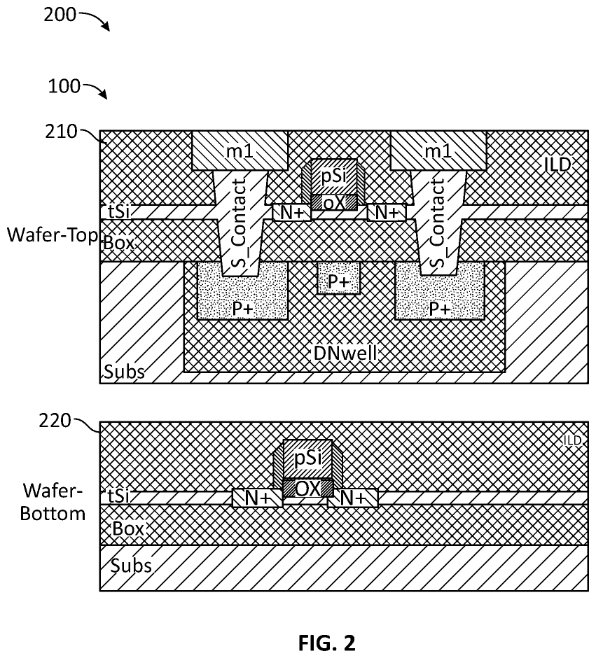

FIG. 2 illustrates an example application 200 in which the bipolar junction transistor device 100 can be used, in accordance with one or more embodiments. As illustrated in FIG. 2, the bipolar junction transistor device 100 can fit between two wafers, in which the bipolar junction transistor device 100 can be used to provide real-time device-level temperature information and/or a robust electrostatic discharge (ESD) protection between the top and bottom wafers 210 and 220. The bipolar junction transistor device 100 can be an ideal device for bandgap reference circuits. All SOI diodes suffer from ideality variability issues. The bipolar junction transistor device 100 is a tunable bipolar ideal for ESD applications, where working distance between various P+ regions/N+ regions can be customized to be a layout-dependent. The bipolar junction transistor device 100 and various fabrication techniques described herein can be used to form either a PNP or a NPN bipolar junction transistor device 100. Additional applications may include a low noise amplifier and automatic applications (Barry Gilbert—adi OP Amps really linear). In addition, the disclosed fabrication techniques can also be extended to SOI for low-temperature solutions. Furthermore, 3D solutions can be unique in the SOI wafer stacking situation, which the disclosed fabrication techniques can also provide.

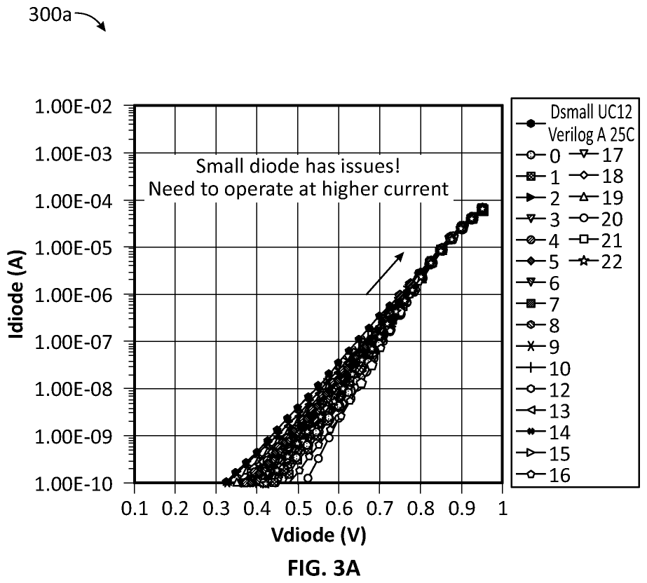

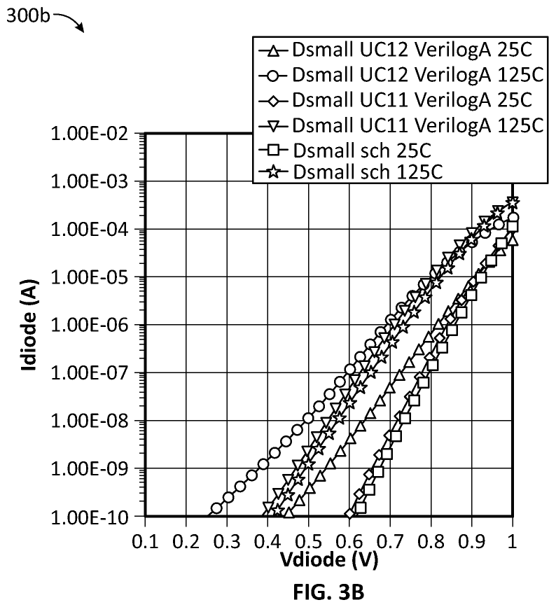

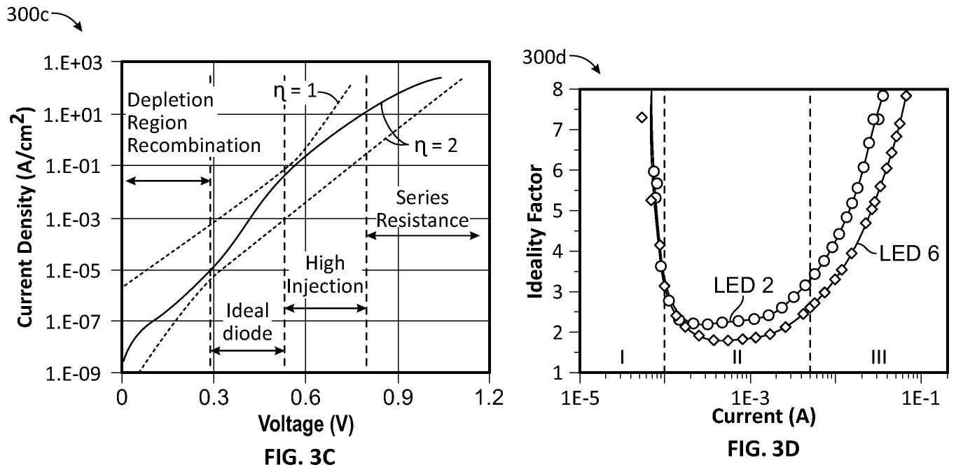

FIGS. 3A-3D show various plots 300a, 300b, 300c, and 300d illustrating silicon-on-insulator (SOI) based diode and bipolar transistor performances. As known in the art, SOI bandgap diodes and bipolars do suffer from poor ideality, especially at smaller diode sizes, as illustrated in plots 300a, 300b, 300c, and 300d of FIGS. 3A, 3B, 3C, and 3D. Poor ideality leads to instability in the circuits-hench its temperature behavior, which is the key for bandgap reference circuits. The various fabrication techniques and the resulting bipolar junction transistor device disclosed herein can help alleviate the issues and improve the performance of such devices.

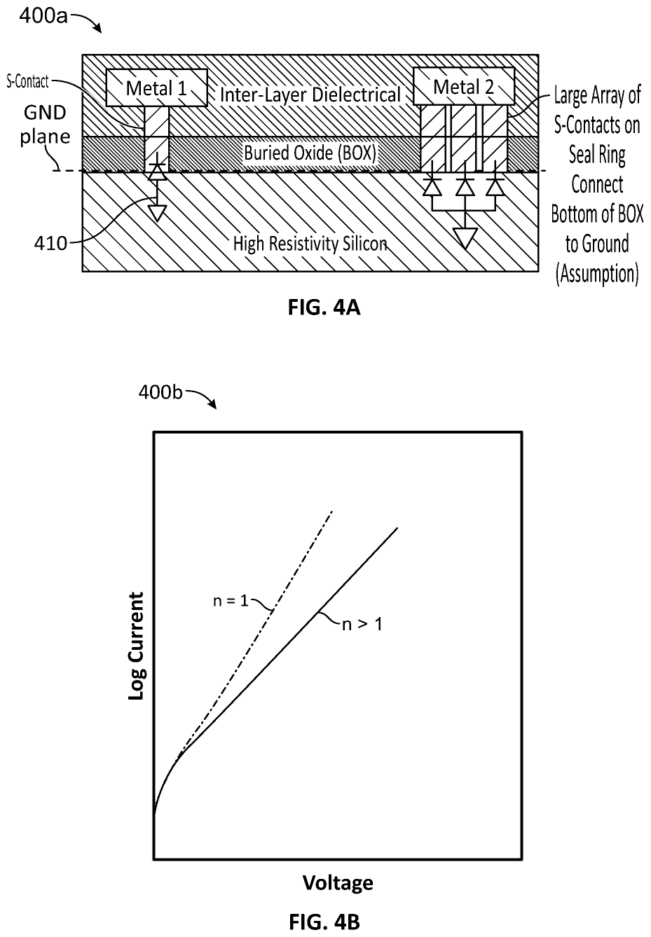

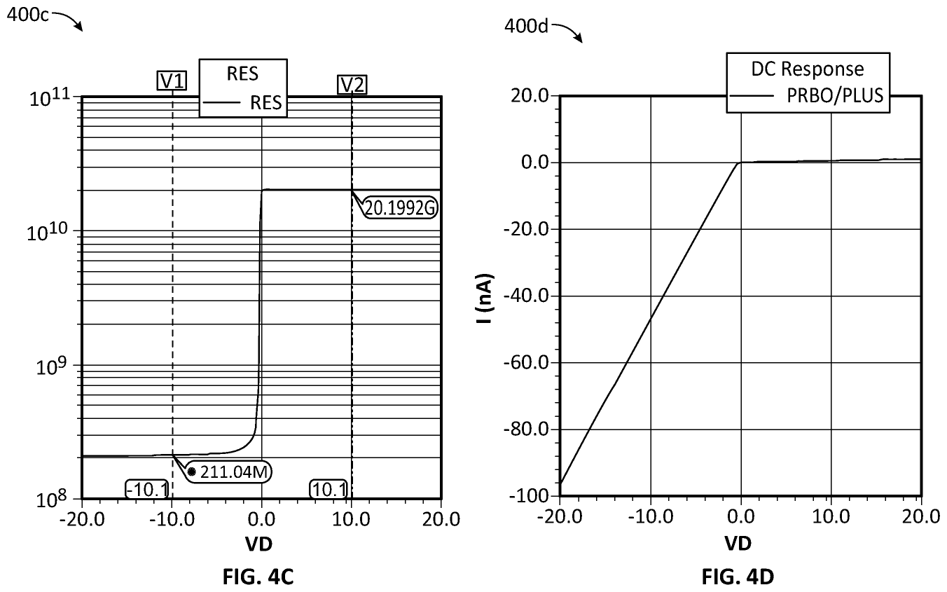

FIGS. 4A-4D show various a schematic diagram 400a and plots 400b, 400c, and 400d illustrating an example silicon-on-insulator (SOI) based diode and bipolar transistor performances. FIG. 4A illustrates an example Schottky contact 410 that is formed when a metal is made contact with a high resistivity silicon, as illustrated in schematic diagram 400a. Plots 400b, 400c, and 400d show how a diode (or bipolar transistor) performs as a function of voltage/current.

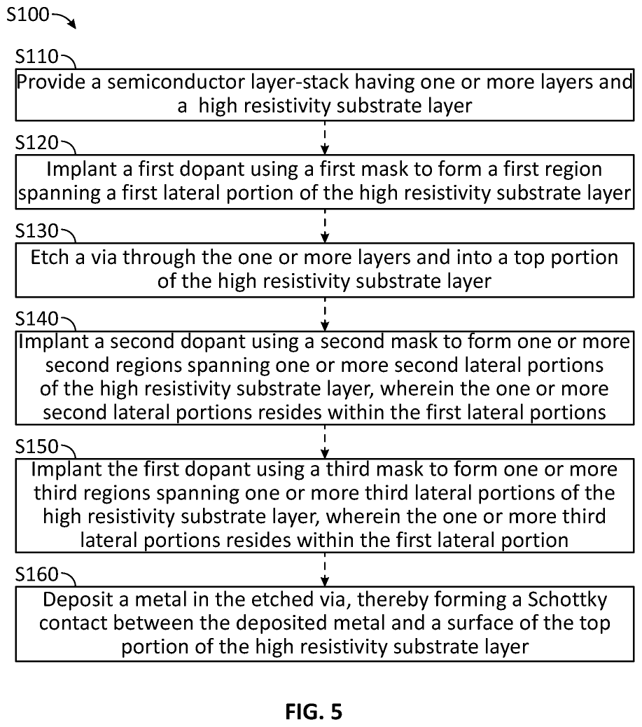

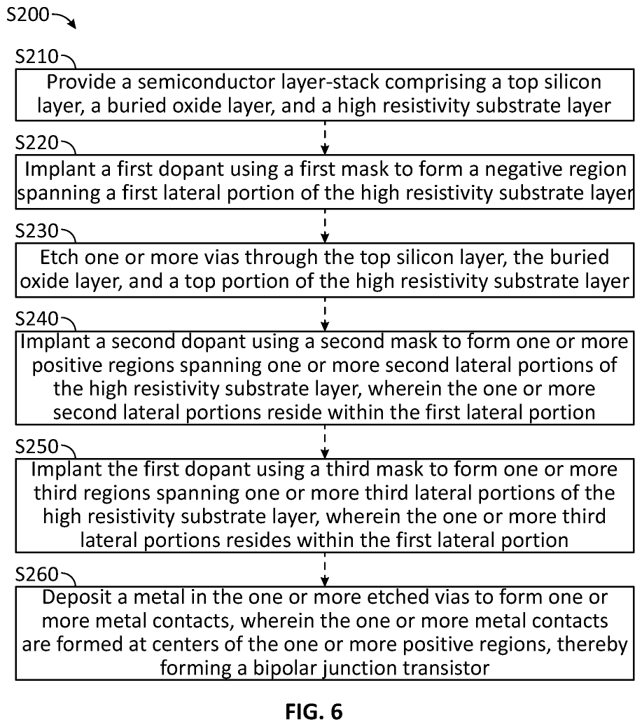

Now referring to FIGS. 5 and 6, which illustrate various fabrication techniques disclosed herein. FIG. 5 illustrates a method S100 of fabricating a device, such as a PNP bipolar junction transistor device or a NPN bipolar junction transistor device, in accordance with various embodiments. The method S100 includes, at step S110, providing a semiconductor layer-stack having one or more layers and a high resistivity substrate layer. The one or more layers may include a top or thin silicon layer and a buried oxide layer. The method S100 includes, at step S120, implanting a first dopant using a first mask to form a first region spanning a first lateral portion of the high resistivity substrate layer. This step is to form a deep well region, such as a deep N well if boron is used as a dopant, or a deep P well if phosphorus or arsenic is used as a dopant.

The method S100 further includes, at step S130, etching a via through the one or more layers and into a top portion of the high resistivity substrate layer. In this step, a via is etched through the thin silicon layer and the buried oxide layer, and stops the etch near the top portion of the high resistivity substrate layer. The method S100 includes, at step S140, implanting a second dopant using a second mask to form one or more second regions spanning one or more second lateral portions of the high resistivity substrate layer, wherein the one or more second lateral portions resides within the first lateral portion. In this step, one or more P+ regions can be formed to be used as an Emitter or a Collector as components of the bipolar junction transistor, if phosphorus or arsenic is used as the dopant. Alternatively, one or more N+ regions can be formed to be used as Base portions as part of the bipolar junction transistor, if boron is used as the dopant.

The method S100 further includes, at step S150, implanting the first dopant using a third mask to form one or more third regions spanning one or more third lateral portions of the high resistivity substrate layer, wherein the one or more third lateral portions resides within the first lateral portion. In this step, one or more N+ regions can be formed to be used as Base portions as components of the bipolar junction transistor, if boron is used as the dopant. Alternatively, one or more P+ regions can be formed to be used as Base portions as part of the bipolar junction transistor, if phosphorus or arsenic is used as the dopant.

In one or more embodiments, the one or more second regions may include three second regions, wherein a middle second region of the three second regions is smaller in lateral dimensions than two outer second regions of the three second regions, and wherein the middle second region is equal distant from the two outer second regions. The middle second region disclosed herein can be used as a floating region that can help reduce the resistance between the two outer second regions, which form the Emitter and Collector of the bipolar junction transistor. In other words, having the floating region helps reduce the current by moving the flow of electrons away from the interface between the buried oxide layer and the high resistivity substrate layer.

In one or more embodiments, the one or more third regions comprise two third regions and wherein the middle second region resides between the two third regions and at an equal distance from each of the two third regions. The middle second region disclosed herein can be used as the floating region and is in between the two third regions, which form the two Bases of the bipolar junction transistor.

In one or more embodiments, etching the via at step S130 can further include etching one or more vias using a fourth mask to form vias at a center of each of the one or more second regions and each of the one or more third regions. In other words, vias are formed at centers of the Emitter, Collector, and Base, where a metal can be deposited into the vias to form metal contacts. However, the middle second region, which acts as the floating region, does not have a via formed at its center since a metal contact is not needed.

In various embodiments, the method S100 may further includes, at step S160, depositing a metal in the etched via to form a Schottky contact between the deposited metal and a surface of the top portion of the high resistivity substrate layer.

In one or more embodiments, the first dopant can be doped at an implantation energy ranging between 100 keV and 800 keV (e.g., high implantation energy or any suitable energy and/or depending on dopant species). In one or more embodiments, the first dopant can be doped at an implantation energy ranging between 150 keV and 500 keV. The high implantation energy is used to form the deep Nwell region (or in the alternative, the deep Pwell region). In one or more embodiments, the second dopant can be doped with an implantation dosage between 10¹² and 5×10¹³ (e.g., high dosage or any suitable dosage and/or depending on dopant species) and at an implantation energy ranging between 10 keV and 100 keV (e.g., low implantation energy or any suitable energy and/or depending on dopant species). This high dosage and low implantation energy for doping is to form P+ regions (or in the alternative, N+ regions), which have shallower depth doped regions with a high concentration of the P+ species (or N+ species). To fabricate a PNP bipolar junction transistor, the first dopant used can be boron and the second dopant used can be phosphorous or arsenic. To fabricate a NPN bipolar junction transistor, the first dopant used can be phosphorous or arsenic, and the second dopant used can be boron.

FIG. 6 illustrates a method S200 of fabricating a bipolar junction transistor, such as a PNP bipolar junction transistor device or a NPN bipolar junction transistor device, in accordance with various embodiments. The method S200 includes, at step S210, providing a semiconductor layer-stack comprising a top silicon layer, a buried oxide layer, and a high resistivity substrate layer; at step S220, implanting a first dopant using a first mask to form a negative region spanning a first lateral portion of the high resistivity substrate layer; at step S230, etching one or more vias through the top silicon layer, the buried oxide layer, and a top portion of the high resistivity substrate layer; at step S240, implanting a second dopant using a second mask to form one or more positive regions spanning one or more second lateral portions of the high resistivity substrate layer, wherein the one or more second lateral portions resides within the first lateral portion; at step S250, implanting the first dopant using a third mask to form one or more third regions spanning one or more third lateral portions of the high resistivity substrate layer, wherein the one or more third lateral portions resides within the first lateral portion; and at step S260, depositing a metal in the one or more etched vias to form one or more metal contacts, wherein the one or more metal contacts are formed at centers of the one or more positive regions, thereby forming a bipolar junction transistor.

In one or more embodiments, the one or more second regions comprise three second regions, wherein a middle second region of the three second regions is smaller in lateral dimensions than two outer second regions of the three second regions, and wherein the middle second region is equal distant from the two outer second regions. The middle second region disclosed herein can be used as a floating region that can help reduce the resistance between the two outer second regions, which form the Emitter and Collector of the bipolar junction transistor. In other words, having the floating region helps reduce the current by moving the flow of electrons away from the interface between the buried oxide layer and the high resistivity substrate layer.

In one or more embodiments, etching the one or more via may further include etching the one or more vias using a fourth mask to form vias at a center of the two outer second regions without forming a via at a center of the middle second region. In one or more embodiments, the fabricated device is a PNP bipolar junction transistor if the first dopant is boron and the second dopant is phosphorous or arsenic. In one or more embodiments, the fabricated device is a NPN bipolar junction transistor if the first dopant is phosphorous or arsenic and the second dopant is boron.

What is claimed is:

1. A method for fabricating a device, comprising:
providing a semiconductor layer-stack having one or more layers and a high resistivity substrate layer;
implanting a first dopant using a first mask to form a first region spanning a first lateral portion of the high resistivity substrate layer;
etching a via through the one or more layers and into a top portion of the high resistivity substrate layer;
implanting a second dopant using a second mask to form one or more second regions spanning one or more second lateral portions of the high resistivity substrate layer, wherein the one or more second lateral portions resides within the first lateral portion; and
implanting the first dopant using a third mask to form one or more third regions spanning one or more third lateral portions of the high resistivity substrate layer, wherein the one or more third lateral portions resides within the first lateral portion.

2. The method of claim 1, wherein the one or more second regions comprise three second regions, wherein a middle second region of the three second regions is smaller in lateral dimensions than two outer second regions of the three second regions, and wherein the middle second region is equal distant from the two outer second regions.

3. The method of claim 2, wherein the one or more third regions comprise two third regions and wherein the middle second region resides between the two third regions and at an equal distance from each of the two third regions.

4. The method of claim 1, wherein the one or more layers comprise a thin silicon layer and a buried oxide layer, and wherein etching the via comprises etching the via through the thin silicon layer and the buried oxide layer, and into the top portion of the high resistivity substrate layer.

5. The method of claim 1, wherein etching the via further comprises etching one or more vias using a fourth mask to form vias at a center of each of the one or more second regions and each of the one or more third regions.

6. The method of claim 2, wherein etching the via further comprises etching one or more vias using a fourth mask to form vias at a center of the two outer second regions without forming a via at a center of the middle second region.

7. The method of claim 1, further comprising:
depositing a metal in the etched via, thereby forming a Schottky contact between the deposited metal and a surface of the top portion of the high resistivity substrate layer.

8. The method of claim 1, wherein the first dopant is doped at an implantation energy ranging between 100 keV and 800 keV (e.g., high implantation energy).

9. The method of claim 1, wherein the second dopant is doped with an implantation dosage between 10¹² and 5×10¹³ (e.g., high dosage) and at an implantation energy ranging between 10 keV and 100 keV (e.g., low implantation energy).

10. The method of claim 1, wherein:
the first dopant is boron, and the second dopant is phosphorous or arsenic; or
the first dopant is phosphorous or arsenic, and the second dopant is boron.

11. A method for fabricating a bipolar junction transistor, comprising:
providing a semiconductor layer-stack comprising a top silicon layer, a buried oxide layer, and a high resistivity substrate layer;
implanting a first dopant using a first mask to form a negative region spanning a first lateral portion of the high resistivity substrate layer;
etching one or more vias through the top silicon layer, the buried oxide layer, and a top portion of the high resistivity substrate layer;
implanting a second dopant using a second mask to form one or more positive regions spanning one or more second lateral portions of the high resistivity substrate layer, wherein the one or more second lateral portions resides within the first lateral portion;
implanting the first dopant using a third mask to form one or more third regions spanning one or more third lateral portions of the high resistivity substrate layer, wherein the one or more third lateral portions resides within the first lateral portion; and
depositing a metal in the one or more etched vias to form one or more metal contacts, wherein the one or more metal contacts are formed at centers of the one or more positive regions, thereby forming a bipolar junction transistor.

12. The method of claim 11, wherein the one or more second regions comprise three second regions, wherein a middle second region of the three second regions is smaller in lateral dimensions than two outer second regions of the three second regions, and wherein the middle second region is equal distant from the two outer second regions.

13. The method of claim 12, wherein etching the one or more via further comprises etching the one or more vias using a fourth mask to form vias at a center of the two outer second regions without forming a via at a center of the middle second region.

14. The method of claim 11, wherein the first dopant is boron, the second dopant is phosphorous or arsenic, and the bipolar junction transistor is a PNP bipolar junction transistor.

15. The method of claim 11, wherein the first dopant is phosphorous or arsenic, the second dopant is boron, and the bipolar junction transistor is a NPN bipolar junction transistor.

16. A device, comprising:
a semiconductor layer-stack having one or more layers and a high resistivity substrate layer, wherein the high resistivity substrate layer comprises:
a first region spanning a first lateral portion of the high resistivity substrate layer, wherein the first region comprises a first dopant,
one or more second regions spanning one or more second lateral portions of the high resistivity substrate layer, wherein the one or more second lateral portions resides within the first lateral portion, wherein the one or more second regions comprise a second dopant, and
one or more third regions spanning one or more third lateral portions of the high resistivity substrate layer, wherein the one or more third lateral portions resides within the first lateral portion, wherein the one or more third regions comprise the first dopant,
a plurality of vias formed through the one or more layers and within a top portion of the high resistivity substrate layer, and
a plurality of metal contacts, wherein each of the plurality of metal contacts is formed within a via of the plurality of vias.

17. The device of claim 16, wherein the one or more second regions comprise three second regions, wherein two outer second regions each have a via form at its center and the middle second region is without a via at its center.

18. The device of claim 16, wherein the one or more second regions comprise three second regions, wherein a middle second region of the three second regions is smaller in lateral dimensions than two outer second regions of the three second regions, and wherein the middle second region is equal distant from the two outer second regions.

19. The device of claim 18, wherein the one or more third regions comprise two third regions and wherein the middle second region resides between the two third regions and at an equal distance from each of the two third regions.

20. The device of claim 16, wherein:
the first dopant is boron, the second dopant is phosphorous or arsenic, and the device is a PNP bipolar junction transistor; or
the first dopant is phosphorous or arsenic, the second dopant is boron, and the device is a NPN bipolar junction transistor.
